(19) United States
(12) Patent Application Publication
(10) Pub. No.: US 2022/0075542 A1
(43) Pub. Date: Mar. 10, 2022

(54) CALIBRATION APPARATUS AND METHOD FOR DATA COMMUNICATION IN A MEMORY SYSTEM

(71) Applicant: SK hynix Inc., Gyeonggi-do (KR)

(72) Inventors: Hung Yung CHO, Gyeonggi-do (KR); Kwan Yong JIN, Gyeonggi-do (KR)

(21) Appl. No.: 17/177,735

(22) Filed: Feb. 17, 2021

(30) Foreign Application Priority Data
Sep. 8, 2020 (KR) 10-2020-0114595

(51) Int. Cl. G06F 3/06

(52) U.S. Cl. CPC G06F 3/0635; G06F 3/0631; G06F 3/0679; G06F 3/0619; G06F 3/0659

(57) ABSTRACT

A memory system includes a memory device including a plurality of memory dies and a controller coupled to the plurality of memory dies via plural data paths. The controller is configured to select a first path among the plural data paths, activate unselected paths among the plural data paths, and perform a calibration operation for data communication between the controller and a first memory die coupled to the controller via the first path among the plural memory dies while the unselected paths are activated.

### CROSS-REFERENCE TO RELATED APPLICATIONS

This patent application claims the benefit of Korean Patent Application No. 10-2020-0114595, filed on Sep. 8, 2020, the entire disclosure of which is incorporated herein by reference.

### TECHNICAL FIELD

One or more embodiments described herein relate to an apparatus and method which performs a calibration operation to control data communication between a controller and a memory device including plural non-volatile memory cells.

### BACKGROUND

Recently, a paradigm for a computing environment has shifted to ubiquitous computing, which enables computer systems to be accessed virtually anytime and anywhere. As a result, the use of portable electronic devices (e.g., mobile phones, digital cameras, notebook computers) is rapidly increasing. Such portable electronic devices may use or include a memory system having at least one memory device, e.g., a data storage device. The data storage device can be used as a main storage device or an auxiliary storage device of a portable electronic device.

Unlike a hard disk, data storage devices that use non-volatile semiconductor memories exhibit improved stability and durability, have no mechanical driving parts (e.g., a mechanical arm), and perform with high data access speeds and relatively low power consumption. Examples of these types of data storage devices include, but are not limited to, Universal Serial Bus (USB) memory devices, memory cards having various interfaces, and solid state drives (SSDs).

### BRIEF DESCRIPTION OF THE DRAWINGS

The description herein makes reference to the accompanying drawings wherein like reference numerals refer to like parts throughout the figures.

FIG. 1 illustrates a memory system according to an embodiment of the present disclosure.

FIG. 2 illustrates a data processing system according to an embodiment of the present disclosure.

FIG. 3 illustrates a memory system according to an embodiment of the present disclosure.

FIG. 4 illustrates channel activation in a memory system according to an embodiment of the present disclosure.

FIG. 5 illustrate a calibration operation for data communication in a memory system according to an embodiment of the present disclosure.

FIG. 6 illustrates a data input/output apparatus for performing the calibration operation.

FIG. 7 illustrates an internal configuration of memory device according to an embodiment of the present disclosure.

FIG. 8 illustrates a channel status for the calibration operation.

FIG. 9 illustrates data transmission windows of the calibration operation and the channel activation.

FIG. 10 illustrates a method for operating a memory system according to an embodiment of the present disclosure.

FIG. 11 illustrates an effect of the calibration operation with the channel activation.

### DETAILED DESCRIPTION

Various embodiments of the disclosure are described below with reference to the accompanying drawings. Elements and features of the disclosure, however, may be configured or arranged differently to form other embodiments, which may be variations of any of the disclosed embodiments.

In this disclosure, the terms “comprise,” “comprising,” “include,” and “including” are open-ended. As used in the appended claims, these terms specify the presence of the stated elements and do not preclude the presence or addition of one or more other elements. The terms in a claim do not foreclose the apparatus from including additional components (e.g., an interface unit, circuitry, etc.).

In this disclosure, references to various features (e.g., elements, structures, modules, components, steps, operations, characteristics, etc.) included in “one embodiment”, “example embodiment”, “an embodiment”, “another embodiment”, “some embodiments”, “various embodiments”, “other embodiments”, “alternative embodiment”, and the like are intended to mean that any such features are included in one or more embodiments of the present disclosure, but may or may not necessarily be combined in the same embodiments.

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational (e.g., is not turned on nor activated). The block/unit/circuit/component used with the “configured to” language include hardware for example, circuits, memory storing program instructions executable to implement the operation, etc. Additionally, “configured to” can include a generic structure (e.g., generic circuitry) that is manipulated by software and/or firmware (e.g., an FPGA or a general-purpose processor executing software) to operate in manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks.

As used in the disclosure, the term ‘circuitry’ may refer to all of the following: (a) hardware-only circuit implementations (such as implementations in only analog and/or digital circuitry) and (b) combinations of circuits and software (and/or firmware), such as (as applicable): (i) to a combination of processor(s) or (ii) to portions of processor(s)/software (including digital signal processor(s)), software, and memory(ies) that work together to cause an apparatus, such as a mobile phone or server, to perform various functions) and (c) circuits, such as a microprocessor(s) or a portion of a microprocessor(s), that require software or firmware for operation, even if the software or firmware is not physically present. This definition of ‘circuitry’ applies to all uses of this term in this application, including in any claims. As a further example, as used in this application, the term “circuitry” also covers an implementation of merely a processor (or multiple processors) or portion of a processor and its (or their) accompanying software and/or firmware. The term “circuitry” also covers, for example, and if applicable to a particular claim element, an integrated circuit for a storage device.

As used herein, the terms “first,” “second,” “third,” and so on are used as labels for nouns that they precede, and do not imply any type of ordering (e.g., spatial, temporal, logical, etc.). The terms “first” and “second” do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term “based on” is used to describe one or more factors that affect a determination. This term does not foreclose additional factors that may affect a determination. That is, a determination may be solely based on those factors or based, at least in part, on those factors. Consider the phrase “determine A based on B.” While in this case, B is a factor that affects the determination of A, such a phrase does not foreclose the determination of A from also being based on C. In other instances, A may be determined based solely on B.

Herein, an item of data or a data item may be a sequence of bits. For example, the data item may include the contents of a file, a portion of the file, a page in memory, an object in an object-oriented program, a digital message, a digital scanned image, a part of a video or audio signal, or any other entity which can be represented by a sequence of bits. According to an embodiment, the data item may include a discrete object. According to another embodiment, the data item may include a unit of information within a transmission packet between two different components.

An embodiment of the disclosure can provide a data processing system and a method for operating the data processing system, which includes components and resources such as a memory system and a host, and is capable of dynamically allocating plural data paths used for data communication between the components based on usages of the components and the resources.

Further, the memory system according to an embodiment of the present disclosure may provide an apparatus and a method capable of improving operational reliability by reducing errors occurring in a process of transmitting and receiving data within a memory system operating at a high speed.

According to an embodiment of the present disclosure, the memory system may employ or adopt an apparatus and a method for performing a calibration operation under a worse situation set in a view of data communication (i.e., transmission/reception).

In addition, an apparatus and a method for performing a data communication calibration operation according to an embodiment of the present disclosure can more accurately determine an operating margin for data transmission/reception between components arranged within a memory system, thereby reducing errors in data transmission/reception between the components. Further, it is possible to reduce influence of interference occurring due to a relative position or arrangement of components or data paths within the memory system.

In an embodiment of the present disclosure, a memory system can include a memory device including a plurality of memory dies; and a controller coupled to the plurality of memory dies via plural data paths. The controller can be configured to select a first path among the plural data paths, activate unselected paths among the plural data paths, and perform a calibration operation for data communication between the controller and a first memory die coupled to the controller via the first path among the plural memory dies while the unselected paths are activated.

The controller can be configured to perform the calibration operation for each memory die individually. An overall calibration window for the calibration operation can be overlapped with an activation window.

The controller can be further configured to store a result of the calibration operation performed for each memory die.

The controller can be further configured to perform the calibration operation to other memory dies coupled to the controller via the first path after the calibration operation to the first memory die is completed, and select a second path among the unselected paths after the calibration operation to the other memory dies is completed.

The controller can be further configured to select a second path among the unselected paths for the calibration operation, after the calibration operation to the first memory die is completed and before the calibration operation to other memory dies coupled to the controller via the first path starts.

The controller can be configured to activate the unselected paths by transmitting dummy data with a program command to at least one memory die coupled to the controller via each of the unselected paths.

The controller can be configured to activate the unselected paths by transmitting dummy data without a program command to at least one memory die coupled to the controller via each of the unselected paths.

The controller can be configured to activate the unselected paths by transmitting a read command to at least one memory die coupled to the controller via each of the unselected paths.

The calibration operation can include a first calibration operation for first data communication from the controller to the first memory die and a second calibration operation for second data communication from the first memory die to the controller.

The controller can be configured to activate the unselected paths with a data pattern which causes the most noise or interference among the plural data paths.

In another embodiment of the present disclosure, a method for operating a memory system including a plurality of memory dies can include selecting a first path among plural data paths for performing a calibration operation, the plural data paths being coupled between a controller and the memory dies; activating unselected paths among the plural data paths; and performing the calibration operation for data communication between a controller and a first memory die coupled to the controller via the first path among the plural memory dies while the unselected paths are activated.

The selecting the first path can include selecting at least one memory die coupled to the controller via the first data path.

The activating of the unselected paths can include selecting at least one memory die coupled to the controller via each of the unselected paths and performing the data communication to a selected memory die.

The calibration operation can be individually and sequentially performed to other dies among the plurality of memory dies. An overall calibration window for the calibration operation can be overlapped with an activation window.

The method can further include either selecting a second path among the unselected paths or selecting another memory die coupled to the controller via the first path, after the calibration operation to the first memory die is completed.

The activating the unselected paths can include selecting at least one memory die coupled to the controller via each of the unselected paths and performing a program operation or a read operation with the at least one memory die.

The performing of program operation or the read operation can include transmitting a data pattern which causes noise or interference among the plural data paths.

The method can further include storing a result of the calibration operation performed for the first memory die.

In another embodiment of the present disclosure, a data input/output apparatus can include plural data transceivers, which are configured to perform data communication to plural devices via plural data paths and arranged to correspond to the plural data paths. A data transceiver selected among the plural data transceivers can perform a calibration operation while unselected transceivers among the plural data transceiver perform data input/output operations. An overall calibration window for the calibration operation can be overlapped with a data input/output window for the data input/output operations.

Each of the plural data transceivers can include a first path allocated for data transmission; a second path allocated for data reception; a delay unit configured to delay the reception data by a delay amount in the second path; and a calibration unit configured to adjust the delay amount of the delay unit through the calibration operation.

In another embodiment of the present disclosure, an operating method of a controller for controlling a memory device through plural paths can include calibrating a selected path while activating all remaining paths other than the selected path among the plural paths.

Embodiments of the present disclosure will now be described with reference to the accompanying drawings, wherein like numbers reference like elements.

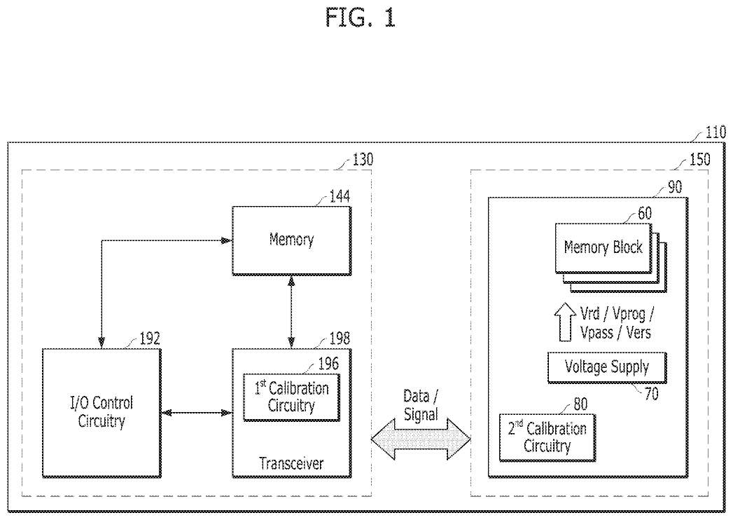

FIG. 1 illustrates a data processing system according to an embodiment of the disclosure.

Referring to FIG. 1, a memory system 110 may include a memory device 150 and a controller 130. The memory device 150 and the controller 130 in the memory system 110 may be considered components or elements physically separated from each other. The memory device 150 and the controller 130 may be connected via at least one data path. For example, the data path may include a channel and/or a way.

According to an embodiment, the memory device 150 and the controller 130 may be components or elements functionally divided. Further, according to an embodiment, the memory device 150 and the controller 130 may be implemented with a single chip or a plurality of chips.

The memory device 150 may include a memory die 90. The memory die 90 may include a plurality of memory blocks 60. The memory block 60 may be understood as a group of non-volatile memory cells in which data is removed together by a single erase operation. Although not illustrated, the memory block 60 may include a page which is a group of non-volatile memory cells that store data together during a single program operation or output data together during a single read operation. For example, one memory block 60 may include a plurality of pages.

Although not shown in FIG. 1, the memory device 150 may include a plurality of memory planes or a plurality of memory dies. According to an embodiment, the memory plane may be considered a logical or a physical partition including at least one memory block 60, a driving circuit capable of controlling an array including a plurality of non-volatile memory cells, and a buffer that can temporarily store data inputted to, or outputted from, non-volatile memory cells.

In addition, according to an embodiment, the memory die may include at least one memory plane. The memory die may be understood as a set of components implemented on a physically distinguishable substrate. Each memory die may be connected to the controller 130 through a data path. Each memory die may include an interface to exchange a piece of data and a signal with the controller 130.

According to an embodiment, the memory device 150 may include at least one memory block 60, at least one memory plane, or at least one memory die. The internal configuration of the memory device 150 shown in FIG. 1 may be different according to performance of the memory system 110. An embodiment of the present disclosure is not limited to the internal configuration shown in FIG. 1.

Referring to FIG. 1, the memory device 150 may include a voltage supply circuit 70 capable of supplying at least some voltage into the memory block 60. The voltage supply circuit 70 may supply a read voltage Vrd, a program voltage Vprog, a pass voltage Vpass, or an erase voltage Vers into a non-volatile memory cell included in the memory block 60. For example, during a read operation for reading data stored in the non-volatile memory cell included in the memory block 60, the voltage supply circuit 70 may supply the read voltage Vrd into a selected non-volatile memory cell. During the program operation for storing data in the non-volatile memory cell included in the memory block 60, the voltage supply circuit 70 may supply the program voltage Vprog into a selected non-volatile memory cell. Also, during a read operation or a program operation performed on the selected nonvolatile memory cell, the voltage supply circuit 70 may supply a pass voltage Vpass into a non-selected nonvolatile memory cell. During the erasing operation for erasing data stored in the non-volatile memory cell included in the memory block 60, the voltage supply circuit 70 may supply the erase voltage Vers into the memory block 60.

The controller 130 may perform a data input/output operation in response to a request input from the external device. For example, when the controller 130 performs a read operation in response to a read request input from an external device, data stored in a plurality of non-volatile memory cells included in the memory device 150 is transferred to the controller 130. For the read operation, the input/output controller 192 may perform address translation to the logical address input from the external device to obtain a physical address, and then transmit a read command to the memory device 150 corresponding to the physical address through the transceiver 198. The transceiver 198 may transmit the read command to the memory device 150 and receive data output from the memory device 150 corresponding to the physical address. The transceiver 198 may store data transferred from the memory device 150 in the memory 144. The input/output controller 192 may output data stored in the memory 144 to the external device in response to the read request.

According to an embodiment, the controller 130 and the memory die 90 in the memory system 110 may be coupled through a data path such as a channel. For example, a plurality of memory dies may be connected to the controller 130 via a single channel.

The controller 130 and the memory die 90 may transmit and receive data according to a preset protocol through a channel. When the controller 130 and the memory die 90 operate independently as an individual entity, an error may occur even though data is transmitted/received by the controller 130 or the memory die 90 according to the preset protocol. For example, a timing of transmitting or receiving data may vary due to an operation delay or a power difference of a clock signal which is supplied to the controller 130 and the memory die 90. In this case, the memory die 90 may not normally receive data transmitted from the controller 130, or the controller 130 may not normally receive data transmitted from the memory die 90. In particular, when timings at which the controller 130 and the memory die 90 transmits or receives data are not aligned or synchronized with each other, the number of errors (e.g., error bits) may increase as the controller 130 and the memory die 90 transmit and receive data at a higher speed. In order to avoid or reduce error bits, two separate devices may perform a calibration operation. The calibration operation can support efficient, quick or accurate transmission and reception of data or signals between the two separate devices.

Referring to FIG. 1, the controller 130 may include first calibration circuitry 196, and the memory die 90 may include a second calibration circuitry 80. For example, the first calibration circuitry 196 may adjust a timing of receiving data or a signal transmitted by the memory die 90, and the second calibration circuitry 80 can control a timing of receiving data or a signal transmitted by the controller 130. According to another embodiment, the first calibration circuitry 196 may adjust a time point at which the controller 130 transmits a signal or data to the memory die 90, and the second calibration circuitry 80 can determine a time point at which the memory die 90 transmits a signal or data to the controller 130. Although not shown, according to an embodiment, the first calibration circuitry 196 included in the controller 130 can adjust a timing of transmitting and receiving a signal or data, but the memory die 90 may not include the second calibration circuitry 80. As described above, a calibration operation for data communication between the controller 130 and the memory die 90 may be differently performed based on internal configurations of the controller 130 and the memory die 90.

When the memory device 150 includes a plurality of memory dies 90, the controller 130 may sequentially or arbitrarily select a memory die among the plurality of memory dies 90 and individually perform the calibration operation for each memory die 90. According to an embodiment, the controller 130 may perform a calibration operation to each of the plurality of memory dies 90 and store a result of the calibration operation corresponding to each memory die 90.

Data transmitted and received through a plurality of data paths (e.g., a plurality of channels) may be deformed, delayed, or distorted for various reasons. For example, when plural data items are transmitted via adjacent data paths, interference may occur between the adjacent data paths. In addition, when plural data items are transmitted in parallel via the plurality of data paths, power in the memory system 110 may become unstable. In order to reduce errors in data communication between the controller 130 and the memory die 90, the controller 130 or the memory die 90 can adjust a timing of transmitting or receiving a signal or data to cope with the transformation, delay or distortion of the signal or the data delivered via the plurality of data paths.

In the memory system 110 according to an embodiment of the disclosure, while performing the calibration operation between the controller 130 and the memory die 90, data or signals are transmitted and received through other data paths except a data path via which the memory die 90 selected for the calibration operation is coupled to the controller 130. In addition, while the calibration operation is performed with a specific memory die, the memory system 110 can perform an operation with a high probability of generating an error via plural data paths except a data path coupling the specific memory die to the controller 130. For example, the memory system 110 can use a data pattern with a high probability of interference, e.g., transmit the data pattern via the plural data paths except the data path reserved for the calibration operation, to create the poorest (e.g., the most burdensome or one of the worst cases) environment within the memory system 110, such as an operating condition that could be the most error prone. While a first memory die connected to a first channel among the plurality of channels and the controller 130 perform a calibration operation, the controller 130 can perform data input/output operation with at least one memory die connected to each of other channels except the first channel. Here, when data or signals are transmitted via a channel by the data input/output operation, the channel is in an active state. But the channel is in an inactive state when any data or signals are not transmitted through the channel. While all channels other than the channel used for the calibration operation are in the active state, the controller 130 may perform the calibration operation with a memory die coupled to the controller 130 via the corresponding channel. Under this environment, the controller 130 and the memory die 90 may obtain a more accurate correlation value for a data transmission/reception timing to avoid transformation, delay, or distortion of data transmitted and received via the plurality of data paths.

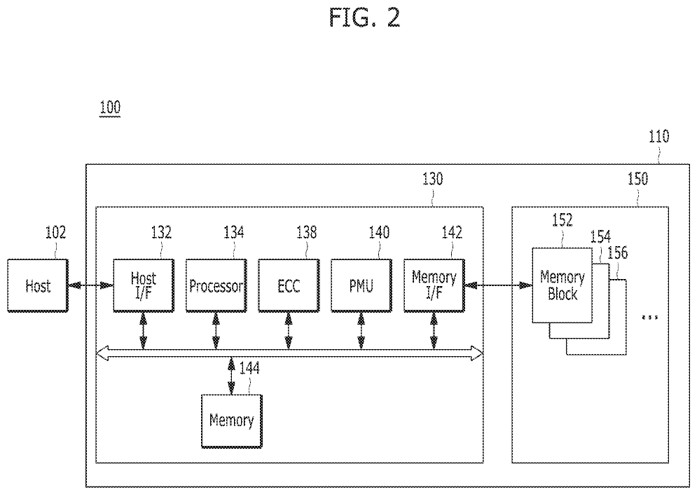

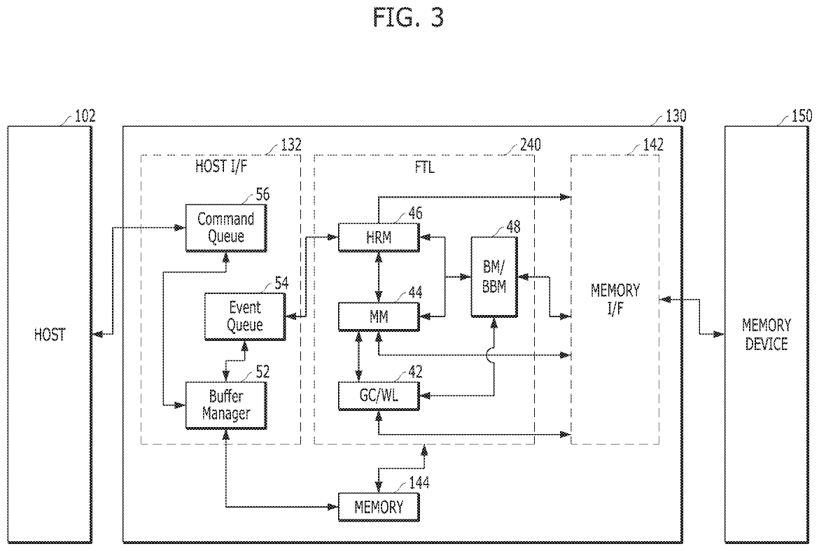

FIGS. 2 and 3 illustrate some operations that may be performed by the memory system 110 according to one or more embodiments of the present disclosure.

Referring to FIG. 2, a data processing system 100 may include a host 102 engaged or coupled with a memory system, such as memory system 110. The host 102 may include a portable electronic device (e.g., a mobile phone, an MP3 player, a laptop computer, etc.) or a non-portable electronic device (e.g., a desktop computer, a game player, a television, a projector, etc.).

The host 102 may also include at least one operating system (OS), which can control functions and operations performed in the host 102. The OS can provide interoperability between the host 102 engaged operatively with the memory system 110 and the user who intends to store data in the memory system 110. The OS may support functions and operations corresponding to user requests. By way of example but not limitation, the OS can be classified into a general operating system and a mobile operating system according to mobility of the host 102. The general operating system may be split into a personal operating system and an enterprise operating system according to system requirements or a user environment. As compared with the personal operating system, the enterprise operating systems can be specialized for securing and supporting high performance computing.

The mobile operating system may be subject to support services or functions for mobility (e.g., a power saving function). The host 102 may include a plurality of operating systems. The host 102 may execute multiple operating systems interlocked with the memory system 110, corresponding to a user request. The host 102 may transmit a plurality of commands corresponding to the user's requests into the memory system 110, thereby performing operations corresponding to commands within the memory system 110.

The controller 130 in the memory system 110 may control the memory device 150 in response to a request or a command input from the host 102. For example, the controller 130 may perform a read operation to provide a piece of data read from the memory device 150 for the host 102 and may perform a write operation (or a program operation) to store a piece of data input from the host 102 in the memory device 150. In order to perform data input/output (I/O) operations, the controller 130 may control and manage internal operations for data read, data program, data erase, or the like.

According to an embodiment, the controller 130 can include a host interface 132, a processor 134, error correction circuitry 138, a power management unit (PMU) 140, a memory interface 142, and a memory 144. Components included in the controller 130 as illustrated in FIG. 2 may vary according structure, function, operation performance, or the like, regarding the memory system 110 among embodiments. For example, the memory system 110 may be implemented with any of various types of storage devices, which may be electrically coupled with the host 102, according to a protocol of a host interface. Non-limiting examples of suitable storage devices include a solid state drive (SSD), a multimedia card (MMC), an embedded MMC (eMMC), a reduced size MMC (RS-MMC), a micro-MMC, a secure digital (SD) card, a mini-SD, a micro-SD, a universal serial bus (USB) storage device, a universal flash storage (UFS) device, a compact flash (CF) card, a smart media (SM) card, a memory stick, and the like. Components in the controller 130 may be added or omitted based on implementation of the memory system 110.

The host 102 and the memory system 110 may include a controller or an interface for transmitting and receiving signals, a piece of data, and the like, in accordance with one or more predetermined protocols. For example, the host interface 132 in the memory system 110 may include an apparatus capable of transmitting signals, a piece of data, and the like, to the host 102 or receiving signals, a piece of data, and the like, input from the host 102.

The host interface 132 included in the controller 130 may receive signals, commands (or requests), and/or a piece of data input from the host 102. For example, the host 102 and the memory system 110 may use a predetermined protocol to transmit and receive a piece of data between each other. Examples of protocols or interfaces supported by the host 102 and the memory system 110 for sending and receiving a piece of data include Universal Serial Bus (USB), Multi-Media Card (MMC), Parallel Advanced Technology Attachment (PATA), Small Computer System Interface (SCSI), Enhanced Small Disk Interface (ESDI), Integrated Drive Electronics (IDE), Peripheral Component Interconnect Express (PCIE), Serial-attached SCSI (SAS), Serial Advanced Technology Attachment (SATA), Mobile Industry Processor Interface (MIPI), and the like. According to an embodiment, the host interface 132 is a type of layer for exchanging a piece of data with the host 102 and is implemented with, or driven by, firmware called a host interface layer (HIL).

The Integrated Drive Electronics (IDE) or Advanced Technology Attachment (ATA) may be used as one of the interfaces for transmitting and receiving a piece of data and, for example, may use a cable including 40 wires connected in parallel to support data transmission and reception between the host 102 and the memory system 110. When a plurality of memory systems 110 are connected to a single host 102, the plurality of memory systems 110 may be divided into a master and a slave by using a position or a dip switch to which the plurality of memory systems 110 are connected. The memory system 110 set as the master may be used as the main memory device. The IDE (ATA) may include, for example, Fast-ATA, ATAPI, and Enhanced IDE (EIDE).

Serial Advanced Technology Attachment (SATA) is a type of serial data communication interface that is compatible with various ATA standards of parallel data communication interfaces which is used by Integrated Drive Electronics (IDE) devices. The 40 wires in the IDE interface can be reduced to six wires in the SATA interface. For example, 40 parallel signals for the IDE can be converted into 6 serial signals for SATA to be transmitted between each other. The SATA has been widely used because of its faster data transmission and reception rate, and its less resource consumption in the host 102 used for data transmission and reception. SATA may support connection with up to 30 external devices to a single transceiver included in the host 102. In addition, SATA can support hot plugging that allows an external device to be attached or detached from the host 102, even while data communication between the host 102 and another device is being executed. Thus, the memory system 110 can be connected or disconnected as an additional device, like a device supported by a Universal Serial Bus (USB) even when the host 102 is powered on. For example, in the host 102 having an eSATA port, the memory system may be freely detached like an external hard disk.

Small Computer System Interface (SCSI) is a type of serial data communication interface used for connection between a computer, a server, and/or other peripheral devices. The SCSI can provide a high transmission speed, as compared with other interfaces such as IDE and SATA. In SCSI, the host 102 and at least one peripheral device (e.g., memory system 110) are connected in series, but data transmission and reception between the host 102 and each peripheral device may be performed through a parallel data communication. In SCSI, it is easy to connect to, or disconnect from, the host 102 a device such as the memory system 110. SCSI can support connections of 15 other devices to a single transceiver included in host 102.

Serial Attached SCSI (SAS) can be understood as a serial data communication version of the SCSI. In SAS, not only the host 102 and a plurality of peripheral devices are connected in series, but also data transmission and reception between the host 102 and each peripheral device may be performed in a serial data communication scheme. SAS can support connection between the host 102 and the peripheral device through a serial cable instead of a parallel cable, to easily manage equipment using SAS and enhance or improve operational reliability and communication performance. SAS may support connections of eight external devices to a single transceiver included in the host 102.

The Non-volatile memory express (NVMe) is a type of interface based at least on a Peripheral Component Interconnect Express (PCIe) designed to increase performance and design flexibility of the host 102, servers, computing devices, and the like equipped with the non-volatile memory system 110. PCIe can use a slot or a specific cable for connecting the host 102 (e.g., a computing device) and the memory system 110 (e.g., a peripheral device). For example, PCIe can use a plurality of pins (for example, 18 pins, 32 pins, 49 pins, 82 pins, etc.) and at least one wire (e.g., x1, x4, x8, x16, etc.) to achieve high speed data communication over several hundred MB per second (e.g., 250 MB/s, 500 MB/s, 984.6250 MB/s, 1969 MB/s, and etc.). According to an embodiment, the PCIe scheme may achieve bandwidths of tens to hundreds of Giga bits per second. A system using the NVMe can make the most of an operation speed of the non-volatile memory system 110, such as an SSD, which operates at a higher speed than a hard disk.

According to an embodiment, the host 102 and the memory system 110 may be connected through a universal serial bus (USB). The Universal Serial Bus (USB) is a type of scalable, hot-pluggable plug-and-play serial interface that can provide cost-effective standard connectivity between the host 102 and a peripheral device, such as a keyboard, a mouse, a joystick, a printer, a scanner, a storage device, a modem, a video camera, and the like. A plurality of peripheral devices such as the memory system 110 may be coupled to a single transceiver included in the host 102.

Referring to FIG. 2, the error correction circuitry 138 can correct error bits of the data to be processed in (e.g., output from) the memory device 150, which may include an error correction code (ECC) encoder and an ECC decoder. The ECC encoder can perform error correction encoding of data to be programmed in the memory device 150 to generate encoded data into which a parity bit is added and store the encoded data in memory device 150. The ECC decoder can detect and correct errors contained in data read from the memory device 150 when the controller 130 reads the data stored in the memory device 150. For example, after performing error correction decoding on the data read from the memory device 150, the error correction circuitry 138 can determine whether the error correction decoding has succeeded and output an instruction signal (e.g., a correction success signal or a correction fail signal). The error correction circuitry 138 can use a parity bit generated during the ECC encoding process for correcting the error bit of the read data. When the number of the error bits is greater than or equal to a threshold number of correctable error bits, the error correction circuitry 138 might not correct error bits but instead may output an error correction fail signal indicating failure in correcting the error bits.

According to an embodiment, the error correction circuitry 138 may perform an error correction operation based on a coded modulation such as a low density parity check (LDPC) code, a Bose-Chaudhuri-Hocquenghem (BCH) code, a turbo code, a Reed-Solomon (RS) code, a convolution code, a recursive systematic code (RSC), a trellis-coded modulation (TCM), a Block coded modulation (BCM), and so on. The error correction circuitry 138 may include all circuits, modules, systems, and/or devices for performing the error correction operation based on at least one of the above described codes.

For example, the ECC decoder may perform hard decision decoding or soft decision decoding to data transmitted from the memory device 150. The hard decision decoding can be understood as one of two methods broadly classified for error correction. Hard decision decoding may include an operation of correcting an error by reading digital data of ‘0’ or ‘1’ from a non-volatile memory cell in the memory device 150. Because the hard decision decoding handles a binary logic signal, the circuit/algorithm design or configuration may be simpler and processing speed may be faster than soft decision decoding.

Soft decision decoding may quantize a threshold voltage of a non-volatile memory cell in the memory device 150 by two or more quantized values (e.g., multiple bit data, approximate values, an analog value, and the like) in order to correct an error based on the two or more quantized values. The controller 130 can receive two or more alphabets or quantized values from a plurality of non-volatile memory cells in the memory device 150, and then perform a decoding based on information generated by characterizing the quantized values as a combination of information such as conditional probability or likelihood.

According to an embodiment, the ECC decoder may use low-density parity-check and generator matrix (LDPC-GM) code among methods designed for the soft decision decoding. The low-density parity-check (LDPC) code uses an algorithm that can read values of data from the memory device 150 in several bits according to reliability, not simply data of 1 or 0 like hard decision decoding, and iteratively repeats it through a message exchange in order to improve reliability of the values. Then, the values are finally determined as data of 1 or 0. For example, a decoding algorithm using LDPC codes can be understood as probabilistic decoding. Hard decision decoding in which the value output from a non-volatile memory cell is coded as 0 or 1. Compared to hard decision decoding, soft decision decoding can determine the value stored in the non-volatile memory cell based on the stochastic information. Regarding bit-flipping (which may be considered an error that can occur in the memory device 150), soft decision decoding may provide improved probability of correcting error and recovering data, as well as provide reliability and stability of corrected data. The LDPC-GM code may have a scheme in which internal LDGM codes can be concatenated in series with high-speed LDPC codes.

According to an embodiment, the ECC decoder may use, for example, low-density parity-check convolutional codes (LDPC-CCs) code for soft decision decoding. The LDPC-CCs code may have a scheme using a linear time encoding and a pipeline decoding based on a variable block length and a shift register.

According to an embodiment, the ECC decoder may use, for example, a Log Likelihood Ratio Turbo Code (LLR-TC) for soft decision decoding. The Log Likelihood Ratio (LLR) may be calculated as a non-linear function for a distance between a sampled value and an ideal value. In addition, Turbo Code (TC) may include a simple code (for example, a Hamming code) in two or three dimensions and repeat decoding in a row direction and a column direction to improve reliability of values.

The power management unit (PMU) 140 may control electrical power provided in the controller 130. The PMU 140 may monitor the electrical power supplied to the memory system 110 (e.g., a voltage supplied to the controller 130) and provide the electrical power to components included in the controller 130. The PMU 140 can not only detect power-on or power-off, but also can generate a trigger signal to enable the memory system 110 to back up a current state urgently when the electrical power supplied to the memory system 110 is unstable. According to an embodiment, the PMU 140 may include a device or a component capable of accumulating electrical power that may be used in an emergency.

The memory interface 142 may serve as an interface for handling commands and data transferred between the controller 130 and the memory device 150, in order to allow the controller 130 to control the memory device 150 in response to a command or a request input from the host 102. The memory interface 142 may generate a control signal for the memory device 150 and may process data input to, or output from, the memory device 150 under the control of the processor 134 in a case when the memory device 150 is a flash memory. For example, when the memory device 150 includes a NAND flash memory, the memory interface 142 includes a NAND flash controller (NFC). The memory interface 142 can provide an interface for handling commands and data between the controller 130 and the memory device 150. In accordance with an embodiment, the memory interface 142 can be implemented through, or driven by, firmware called a Flash Interface Layer (FIL) for exchanging data with the memory device 150.

According to an embodiment, the memory interface 142 may support an open NAND flash interface (ONFi), a toggle mode, or the like, for data input/output with the memory device 150. For example, the ONFi may use a data path (e.g., a channel, a way, etc.) that includes at least one signal line capable of supporting bi-directional transmission and reception in a unit of 8-bit or 16-bit data. Data communication between the controller 130 and the memory device 150 can be achieved through at least one interface regarding an asynchronous single data rate (SDR), a synchronous double data rate (DDR), and a toggle double data rate (DDR).

The memory 144 may be a type of working memory in the memory system 110 or the controller 130, while storing temporary or transactional data occurred or delivered for operations in the memory system 110 and the controller 130. For example, the memory 144 may temporarily store read data output from the memory device 150 in response to a request from the host 102, before the read data is output to the host 102. In addition, the controller 130 may temporarily store write data input from the host 102 in the memory 144, before programming the write data in the memory device 150. When the controller 130 controls operations such as data read, data write, data program, data erase, etc., of the memory device 150, a piece of data transmitted or generated between the controller 130 and the memory device 150 of the memory system 110 may be stored in the memory 144.

In addition to the read data or write data, the memory 144 may store information (e.g., map data, read requests, program requests, etc.) used for inputting or outputting data between the host 102 and the memory device 150. According to an embodiment, the memory 144 may include a command queue, a program memory, a data memory, a write buffer/cache, a read buffer/cache, a data buffer/cache, a map buffer/cache, and/or the like. The controller 130 may allocate some storage space in the memory 144 for a component which is established to carry out a data input/output operation. For example, the write buffer established in the memory 144 may be used to temporarily store target data subject to a program operation.

In an embodiment, the memory 144 may be implemented with a volatile memory. For example, the memory 144 may be implemented with a static random access memory (SRAM), a dynamic random access memory (DRAM), or both. Although FIG. 2 illustrates, for example, the memory 144 disposed within the controller 130, the embodiments are not limited thereto. The memory 144 may be located within or external to the controller 130. For instance, the memory 144 may be embodied by an external volatile memory having a memory interface transferring data and/or signals between the memory 144 and the controller 130.

The processor 134 may control the overall operations of the memory system 110. For example, the processor 134 can control a program operation or a read operation of the memory device 150, in response to a write request or a read request entered from the host 102. According to an embodiment, the processor 134 may execute firmware to control the program operation or the read operation in the memory system 110. Herein, the firmware may be referred to as a flash translation layer (FTL). An example of the FTL is later described in detail, referring to FIG. 3. According to an embodiment, the processor 134 may be implemented with a microprocessor or a central processing unit (CPU).

According to an embodiment, the memory system 110 may be implemented with at least one multi-core processor. The multi-core processor is a type of circuit or chip in which two or more cores, which are considered distinct processing regions, are integrated. For example, when a plurality of cores in the multi-core processor drive or execute a plurality of flash translation layers (FTLs) independently, data input/output speed (or performance) of the memory system 110 may be improved. According to an embodiment, the data input/output (I/O) operations in the memory system 110 may be independently performed through different cores in the multi-core processor.

The processor 134 in the controller 130 may perform an operation corresponding to a request or a command input from the host 102. Further, the memory system 110 may be independent of a command or a request input from an external device such as the host 102. In one case, an operation performed by the controller 130 in response to the request or the command input from the host 102 may be considered a foreground operation, while an operation performed by the controller 130 independently (e.g., regardless the request or the command input from the host 102) may be considered a background operation. The controller 130 can perform foreground or background operations for read, write or program, erase and the like, regarding a piece of data in the memory device 150. In addition, a parameter set operation corresponding to a set parameter command or a set feature command as a set command transmitted from the host 102 may be considered a foreground operation. As a background operation without a command transmitted from the host 102, the controller 130 can perform garbage collection (GC), wear leveling (WL), bad block management for identifying and processing bad blocks, or the like. The background operations may be performed in relation to a plurality of memory blocks 152, 154, 156 included in the memory device 150.

According an embodiment, substantially similar operations may be performed as both the foreground operation and the background operation. For example, when the memory system 110 performs garbage collection in response to a request or a command input from the host 102 (e.g., Manual GC), garbage collection can be considered a foreground operation. When the memory system 110 performs garbage collection independently of the host 102 (e.g., Auto GC), garbage collection can be considered a background operation.

When the memory device 150 includes a plurality of dies (or a plurality of chips) including non-volatile memory cells, the controller may be configured to perform parallel processing regarding plural requests or commands input from the host 102 in order to improve performance of the memory system 110. For example, the transmitted requests or commands may be divided and processed in parallel within at least some of a plurality of planes, a plurality of dies or a plurality of chips included in the memory device 150. The memory interface 142 in the controller 130 may be connected to a plurality of planes, dies or chips in the memory device 150 through at least one channel and at least one way. When the controller 130 distributes and stores data in the plurality of dies through each channel or each way in response to requests or commands associated with a plurality of pages including non-volatile memory cells, plural operations corresponding to the requests or the commands can be performed individually or in parallel. Such a processing method or scheme can be considered as an interleaving method. Because data input/output speed of the memory system 110 operating with the interleaving method may be faster than that without the interleaving method, data I/O performance of the memory system 110 can be improved.

By way of example but not limitation, the controller 130 can recognize statuses regarding a plurality of channels (or ways) associated with a plurality of memory dies included in the memory device 150. The controller 130 may determine the status of each channel or each way as one of, for example, a busy status, a ready status, an active status, an idle status, a normal status, and/or an abnormal status. The determination of which channel or way an instruction (and/or a data) is delivered through by the controller can be associated with a physical block address, e.g., which die(s) the instruction (and/or the data) is delivered into. The controller 130 can refer to descriptors delivered from the memory device 150. The descriptors can include a block or page of parameters that describe something about the memory device 150, which is data with a set format or structure. For instance, the descriptors may include device descriptors, configuration descriptors, unit descriptors, and the like. The controller 130 can refer to, or use, the descriptors to determine which channel(s) or way(s) an instruction or a data is exchanged via.

Referring to FIG. 2, the memory device 150 in the memory system 110 may include the plurality of memory blocks 152, 154, 156. Each of the plurality of memory blocks 152, 154, 156 includes a plurality of non-volatile memory cells. According to an embodiment, the memory block 152, 154, 156 can be a group of non-volatile memory cells erased together. The memory block 152, 154, 156 may include a plurality of pages which is a group of non-volatile memory cells read or programmed together. In one embodiment, each memory block 152, 154, 156 may have a three-dimensional stack structure for high integration. Further, the memory device 150 may include a plurality of dies, each die including a plurality of planes, each plane including the plurality of memory blocks 152, 154, 156. Configuration of the memory device 150 can be different for performance of the memory system 110.

In the memory device 150 shown in FIG. 2, the plurality of memory blocks 152, 154, 156 are included. The plurality of memory blocks 152, 154, 156 can be any of single-level cell (SLC) memory blocks, multi-level cell (MLC) memory blocks, or the like, according to the number of bits that can be stored or represented in one memory cell. An SLC memory block includes a plurality of pages implemented by memory cells, each storing one bit of data. An SLC memory block can have high data I/O operation performance and high durability. The MLC memory block includes a plurality of pages implemented by memory cells, each storing multi-bit data (e.g., two bits or more). The MLC memory block can have larger storage capacity for the same space compared to the SLC memory block. The MLC memory block can be highly integrated in view of storage capacity.

In an embodiment, the memory device 150 may be implemented with MLC memory blocks such as a double level cell (DLC) memory block, a triple-level cell (TLC) memory block, a quadruple-level cell (QLC) memory block and a combination thereof. The double-level cell (DLC) memory block may include a plurality of pages implemented by memory cells, each capable of storing 2-bit data. The triple-level cell (TLC) memory block can include a plurality of pages implemented by memory cells, each capable of storing 3-bit data. The quadruple-level cell (QLC) memory block can include a plurality of pages implemented by memory cells, each capable of storing 4-bit data. In another embodiment, the memory device 150 can be implemented with a block including a plurality of pages implemented by memory cells, each capable of storing five or more bits of data.

According to an embodiment, the controller 130 may use a multi-level cell (MLC) memory block included in the memory device 150 such as an SLC memory block that stores one-bit data in one memory cell. A data input/output speed of the multi-level cell (MLC) memory block can be slower than that of the SLC memory block. That is, when the MLC memory block is used as the SLC memory block, a margin for a read or program operation can be reduced. The controller can utilize a faster data input/output speed of the multi-level cell (MLC) memory block when using the multi-level cell (MLC) memory block as the SLC memory block. For example, the controller 130 can use the MLC memory block as a buffer to temporarily store a piece of data, because the buffer may require a high data input/output speed for improving performance of the memory system 110.

Further, according to an embodiment, the controller 130 may program pieces of data in a multi-level cell (MLC) a plurality of times without performing an erase operation on a specific MLC memory block included in the memory device 150. Non-volatile memory cells have a feature that does not support data overwrite. However, the controller 130 may use a feature in which a multi-level cell (MLC) may store multi-bit data, in order to program plural pieces of 1-bit data in the MLC a plurality of times. For a MLC overwrite operation, the controller 130 may store the number of program times as separate operation information when a single piece of 1-bit data is programmed in a non-volatile memory cell. According to an embodiment, an operation for uniformly levelling threshold voltages of non-volatile memory cells can be carried out before another piece of data is overwritten in the same non-volatile memory cells.

In an embodiment, the memory device 150 is embodied as a non-volatile memory such as a flash memory, for example, as a NAND flash memory, a NOR flash memory, and the like. In an embodiment, the memory device 150 may be implemented by at least one of a phase change random access memory (PCRAM), a ferroelectrics random access memory (FRAM), a spin injection magnetic memory (STT-RAM), and a spin transfer torque magnetic random access memory (STT-MRAM), or the like.

Referring to FIG. 3, a controller 130 in a memory system operates along with the host 102 and the memory device 150. As illustrated, the controller 130 includes a host interface 132, a flash translation layer (FTL) 240, as well as the memory interface 142, and the memory 144 previously identified in connection with FIG. 2.

According to an embodiment, the error correction circuitry 138 illustrated in FIG. 2 may be included in the flash translation layer (FTL) 240. In another embodiment, the error correction circuitry 138 may be implemented as a separate module, a circuit, firmware, or the like, which is included in, or associated with, the controller 130.

The host interface 132 may be capable of handling commands, data, and the like transmitted from the host 102. By way of example but not limitation, the host interface 132 may include a command queue 56, a buffer manager 52, and an event queue 54. The command queue 56 may sequentially store commands, data, and the like, received from the host 102 and output them to the buffer manager 52, for example, in an order in which they are stored. The buffer manager 52 may classify, manage, or adjust the commands, the data, and the like, which are received from the command queue 56. The event queue 54 may sequentially transmit events for processing the commands, the data, and the like, received from the buffer manager 52.

A plurality of commands or data of the same characteristic (e.g., read or write commands) may be transmitted from the host 102, or plurality of commands and data of different characteristics may be transmitted to the memory system 110 after being mixed or jumbled by the host 102. For example, a plurality of commands for reading data (read commands) may be delivered, or commands for reading data (read command) and programming/writing data (write command) may be alternately transmitted to the memory system 110. The host interface 132 may store commands, data, and the like, which are transmitted from the host 102, to the command queue 56 sequentially. Thereafter, the host interface 132 may estimate or predict what type of internal operation the controller 130 will perform according to the characteristics of commands, data, and the like, which have been entered from the host 102. The host interface 132 can determine a processing order and a priority of commands, data and the like, based at least on their characteristics.

According to characteristics of commands, data, and the like transmitted from the host 102, the buffer manager 52 in the host interface 132 is configured to determine whether the buffer manager should store commands, data, and the like, in the memory 144, or whether the buffer manager should deliver the commands, the data, and the like into the flash translation layer (FTL) 240. The event queue 54 receives events, entered from the buffer manager 52, which are to be internally executed and processed by the memory system 110 or the controller 130 in response to the commands, the data, and the like, transmitted from the host 102, in order to deliver the events into the flash translation layer (FTL) 240 in the order received.

In accordance with an embodiment, the flash translation layer (FTL) 240 illustrated in FIG. 3 may implement a multi-thread scheme to perform the data input/output (I/O) operations. A multi-thread FTL may be implemented through a multi-core processor using multi-thread included in the controller 130.

In accordance with an embodiment, the flash translation layer (FTL) 240 can include a host request manager (HRM) 46, a map manager (MM) 44, a state manager 42, and a block manager 48. The host request manager (HRM) 46 can manage the events entered from the event queue 54. The map manager (MM) 44 can handle or control a map data. The state manager 42 can perform garbage collection (GC) or wear leveling (WL). The block manager 48 can execute commands or instructions onto a block in the memory device 150.

By way of example but not limitation, the host request manager (HRM) 46 can use the map manager (MM) 44 and the block manager 48 to handle or process requests according to the read and program commands, and events which are delivered from the host interface 132. The host request manager (HRM) 46 can send an inquiry request to the map manager (MM) 44, to determine a physical address corresponding to the logical address which is entered with the events. The host request manager (HRM) 46 can send a read request with the physical address to the memory interface 142, to process the read request (handle the events). In an embodiment, the host request manager (HRM) 46 can send a program request (write request) to the block manager 48 to program data to a specific empty page (no data) in the memory device 150, and then can transmit a map update request corresponding to the program request to the map manager (MM) 44, in order to update an item relevant to the programmed data in information of mapping the logical-physical addresses to each other.

The block manager 48 can convert a program request delivered from the host request manager (HRM) 46, the map manager (MM) 44, and/or the state manager 42, into a flash program request used for the memory device 150 in order to manage flash blocks in the memory device 150. To maximize or enhance program or write performance of the memory system 110 (e.g., see FIG. 2), the block manager 48 may collect program requests and send flash program requests for multiple-plane and one-shot program operations to the memory interface 142. In an embodiment, the block manager 48 sends several flash program requests to the memory interface 142 to enhance or maximize parallel processing of the multi-channel and multi-directional flash controller.

In an embodiment, the block manager 48 can be configured to manage blocks in the memory device 150 according to the number of valid pages, select and erase blocks having no valid pages when a free block is needed, and select a block including the least number of valid pages when it is determined that garbage collection is to be performed. The state manager 42 can perform garbage collection to move the valid data to an empty block and erase the blocks containing the moved valid data so that the block manager 48 may have enough free blocks (empty blocks with no data). When the block manager 48 provides information regarding a block to be erased to the state manager 42, the state manager 42 may check all flash pages of the block to be erased to determine whether each page is valid.

For example, to determine validity of each page, the state manager 42 can identify a logical address recorded in an out-of-band (OOB) area of each page. To determine whether each page is valid, the state manager 42 can compare the physical address of the page with the physical address mapped to the logical address obtained from the inquiry request. The state manager 42 sends a program request to the block manager 48 for each valid page. A mapping table can be updated through the update of the map manager 44 when the program operation is complete.

The map manager 44 can manage a logical-physical mapping table. The map manager 44 can process various requests, for example, queries, updates, and the like, which are generated by the host request manager (HRM) 46 or the state manager 42. The map manager 44 may store the entire mapping table in the memory device 150 (e.g., a flash/non-volatile memory) and cache mapping entries according to the storage capacity of the memory 144. When a map cache miss occurs while processing inquiry or update requests, the map manager 44 may send a read request to the memory interface 142 to load a relevant mapping table stored in the memory device 150. When the number of dirty cache blocks in the map manager 44 exceeds a certain threshold, a program request can be sent to the block manager 48 so that a clean cache block is made and the dirty map table may be stored in the memory device 150.

When garbage collection is performed, the state manager 42 copies valid page(s) into a free block, and the host request manager (HRM) 46 can program the latest version of the data for the same logical address of the page and currently issue an update request. When the state manager 42 requests the map update in a state in which copying of valid page(s) is not completed normally, the map manager 44 might not perform the mapping table update. This is because the map request is issued with old physical information when the state manger 42 requests a map update and a valid page copy is completed later. The map manager 44 may perform a map update operation to ensure accuracy when, or only if, the latest map table still points to the old physical address.

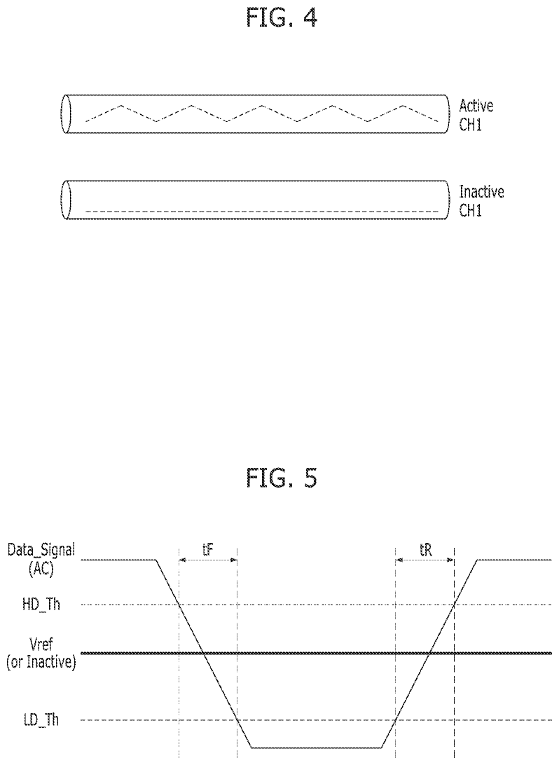

FIG. 4 illustrates channel activation in a memory system according to an embodiment of the present disclosure. A first channel CH1 illustrated in FIG. 4 may be understood as an example of a data path included in the memory system 110 described in FIGS. 1 to 3.

Referring to FIG. 4, the first channel CH1 may have one of two states. One of the two states may be the active state, and the other may be the inactive state. Here, the active state may refer to a state in which data or signals are transmitted via the first channel CH1. Here, there are no restrictions on data or signals. The inactive state may be a state in which there is no data or signal transmitted via the first channel CH1.

According to an embodiment, the first channel CH1 may have various operating states. For example, when the first channel CH1 is used by the controller 130 or the memory die 90, the first channel CH1 may be in a busy state. When the first channel CH1 is not used by the controller 130 or the memory die 90, the first channel CH1 may be in an idle state. Herein, the busy state can be distinguished from the active state. For example, the busy state may indicate a section in which the first channel CH1 is allocated, held or occupied by the controller 130 or the memory die 90 even though data or signals are not actually delivered via the first channel CH1. However, the active state may indicate a section in which data or signals are being transmitted by the controller 130 or the memory die 90. Even if adjacent data paths are in the busy state, interference or noise may not occur when any data or signal is not actually being transmitted by the controller 130 or the memory die 90. However, when an adjacent data path is in an active state, interference or noise may be caused by data or signals transmitted through the adjacent data path.

Because the calibration operation generally uses a simple data pattern, a data transmission window for the calibration operation may not be long (refer to FIG. 9). Accordingly, while performing the calibration operation through a specific channel, the controller 130 may perform data input/output operations through all other channels to generate the interference or noise which may affect the specific channel. In this case, a data transmission window for the data input/output operation may be longer than the data transmission window for the calibration operation. In addition, the data transmission window for the calibration operation may be overlapped with the data transmission window for the data input/output operation. In this disclosure, the data transmission window or a data input/output window may refer to as a time section when any data or any signal is transmitted or delivered between two components through a data path, even though all designed for different operations or purposes, as described with reference to FIGS. 4 to 9. A data transmission window for an activation operation may be called an activation window, and a data transmission window for a calibration operation may be called a calibration window.

FIG. 5 illustrates a calibration operation for data communication in a memory system according to an embodiment of the present disclosure. For example, the calibration operation shown in FIG. 5 may be performed by the first calibration circuitry 196 and the second calibration circuitry 80.

Referring to FIG. 5, the data or signal Data_Signal transmitted through the data path may be considered an alternating current (AC) signal (e.g., a signal having an alternating voltage which will make an alternating current flow). The data or signal Data_Signal transmitted and received by the controller 130 and the memory die 90 in the memory system 110 (refer to FIGS. 1 to 3) may be recognized as a digital value, but the data or signals Data_Signal transmitted through a data path may be substantially similar with an alternating current signal having a continuous waveform in which the voltage level can be varied. Even if the data or signal Data_Signal transmitted by the controller 130 or the memory die 90 is an AC signal, a receiver included in the controller 130 or the memory die 90 can determine that a received signal has a logic high value when the AC signal has a higher level than a reference HD_Th or a logic low value when the AC signal has a lower level than the second reference LD_Th. Accordingly, the receiver can recognize digital values from the continuous waveform of the data or signals Data_Signal.

Furthermore, when the data path is in an inactive state in which no data or signal Data_Signal is transmitted, the voltage level of the data path may be maintained at a reference level Vref. In FIG. 5, the reference level Vref is between the first reference HD_Th and the second reference LD_Th. But, according to another embodiment, the reference level Vref may be higher than the first reference HD_Th or lower than the second reference LD_Th. The reference level Vref, the first reference HD_Th, and the second reference LD_Th may be varied according to design and performance of receiver or transmitter included in the controller 130 and the memory die 90.

Referring to FIG. 5, the data or signal Data_Signal may be changed from a logic high level to a logic low level, or vice versa (i.e., from the logic low level to the logic high level). When the data or signal Data_Signal is changed from the logic high level to the logic low level, a receiver may not recognize an accurate digital value of the data or signal Data_Signal in a falling period tF in which the data or signal Data_Signal has a voltage level between the first reference HD_Th and the second reference LD_Th. Alternatively, when the data or signal Data_Signal is changed from the logic low level to the logic high level, the receiver may not recognize an accurate digital value of the data or signal Data_Signal in a rising period tR in which the data or signal Data_Signal has a voltage level between the first reference HD_Th and the second reference LD_Th. That is, when the receiver extracts a digital value from the data or signal Data_Signal in the falling period tF or the rising period tR, a possibility of generating an error (e.g., a possibility that the receiver wrongly recognizes a digital value of the data or signal Data_Signal) can increase. Accordingly, through the calibration operation, the controller 130 or the memory die 90 may avoid that the receiver recognizes the data or signal Data_Signal in the falling period tF or the rising period tR. Further, through the calibration operation, the controller 130 or the memory die 90 can adjust a reception window so that the receiver can accurately recognize the data or signal Data_Signal between the falling period tF and the rising period tR. For example, when the reception window is in the falling period tF, the controller 130 or the memory die 90 may delay the reception window by an amount corresponding to a result of the calibration operation, so that the reception window shifts after the falling period tF. By delaying the reception window, the controller 130 or the memory die 90 can adjust the reception window to be arranged between the falling period tF and the rising period tR.

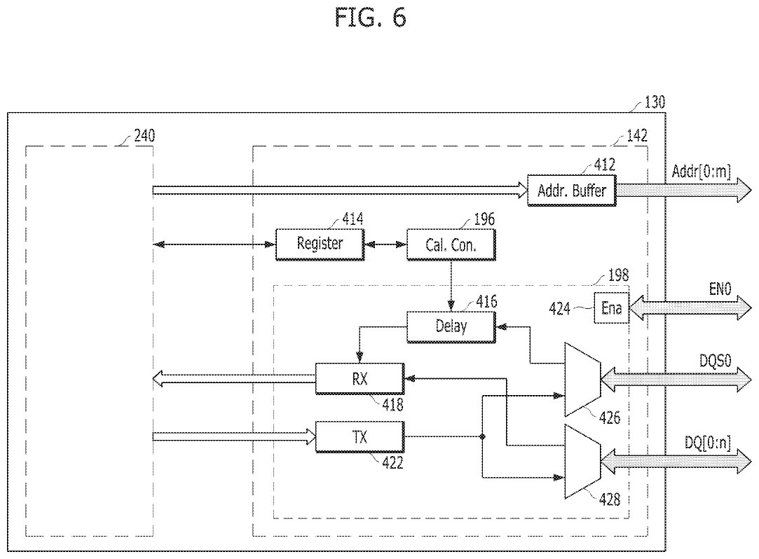

FIG. 6 illustrates a data input/output apparatus for performing the calibration operation. The data input/output apparatus described in FIG. 6 is an example included in the controller 130 shown in FIGS. 1 to 3. According to an embodiment, the data input/output apparatus may also be included in the memory die 90. Or, the data input/output apparatus may be included in a device or a module that is capable of transmitting and receiving data within the memory system 110.

Referring to FIG. 6, the memory interface 142 in the controller 130 may include a transceiver 198. The transceiver 198 may perform data communication with the memory device 150 or the memory die 90.

When the controller 130 performs a read operation, the flash translation layer (FTL) 240 may transmit a read command with a physical address to the memory interface 142. The physical address is temporarily stored in an address buffer 412 in the memory interface 142. The memory interface 142 may transfer the physical address stored in the address buffer 412 to the memory die 90 through an address channel or path Addr[0:m].

In addition, the memory interface 142 may receive information for controlling the memory device 150 or the memory die 90 from the flash translation layer (FTL) 240. The memory interface 142 may deliver the information obtained from the memory device 150 or the memory die 90 into the flash translation layer (FTL) 240. Such information may be stored in a register 414. For example, the first calibration circuitry 196 may perform a calibration operation with the memory die 90 and store a result of the calibration operation in the register 414. The first calibration circuitry 196 may control the transceiver 198 based on a result of the calibration operation.

The transceiver 198 may output or receive data. The transceiver 198 can include an enable unit 424 that receives an enable signal ENO and operates the transceiver 198, a first multiplexer 428 that outputs or receives data DQ[0:n], and a second multiplexer 426 that outputs or receives a data strobe signal DQS0. The data strobe signal DQS0 is a type of clock signal, and may be output along with the data DQ[0:n]. When the controller 130 outputs the data DQ[0:n] to the memory device 150 or the memory die 90, the controller 130 can output the data strobe signal DQS0 corresponding to the data DQ[0:n] to the memory device 150 or the memory die 90. Similarly, when the memory die 90 outputs data DQ[0:n] corresponding to the read request, the memory die 90 may output the data strobe signal DQS0 corresponding to the data DQ[0:n] to the controller 130.

The transceiver 198 includes a data reception path used for receiving data transmitted from another device and a data transmission path used for transmitting data to another device. The data reception and transmission paths are coupled to the first multiplexer 428 and the second multiplexer 426. Referring to FIG. 6, there is no delay in the data transmission path coupled from a transmitter 422 to the first multiplexer 428 and the second multiplexer 426 within the transceiver 198. However, the delay unit 416 is included in the data reception path coupled from a receiver 418 to the first multiplexer 428 and the second multiplexer 426. The delay unit 416 may delay the data strobe signal DQS0 input from another device without delaying the data DQ[0:n].

The delay unit 416 may delay the data strobe signal DQS0 by a delay amount which is adjusted by the first calibration circuitry 196. The first calibration circuitry 196 may perform the calibration operation to determine when to receive data DQ[0:n] transmitted from the memory die 90. The first calibration circuitry 196 may adjust the delay amount of the delay unit 416 according to the result of the calibration operation. The receiver 418 may detect and recognize data DQ[0:n] based on the data strobe signal DQS0 delayed by the delay unit 416 under the control of the first calibration circuitry 196.

FIG. 6 describes an example in which a result of the calibration operation is applied to the data reception path used for data received by the transceiver 198. According to another embodiment, the result of the calibration operation can be applied to the data transmission path for data output to another device. Further, in another embodiment, the result of the calibration operation can also be applied to both the data reception path and the data transmission path. In addition, according to another embodiment, the first calibration circuitry 196 may control a delay amount of data DQ[0:n] other than the data strobe signal DQS0.

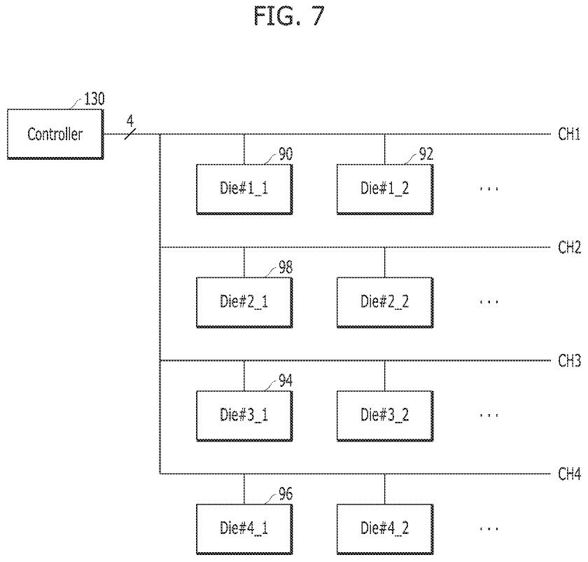

FIG. 7 illustrates an internal configuration of memory device according to an embodiment of the present disclosure.

Referring to FIG. 7, the memory system 110 may include a controller 130 and a plurality of memory dies 90, 92, 94, 96 and 98. The controller 130 may be coupled to the plurality of memory dies 90, 92, 94, 96 and 98 via a plurality of channels CH1, CH2, CH3 and CH4. According to an embodiment, plural memory dies 90 and 92 may be connected to the controller 130 via a first channel CH1. Herein, the number of channels and the number of memory dies may be changed based on design or operating performance of the memory system 110. Also, the number of memory dies coupled to the controller 130 via a single channel may be changed according to the operating performance of the memory system 110.

The plurality of memory dies 90, 92, 94, 96 and 98 may operate independently. Operating environments and conditions for the plurality of memory dies 90, 92, 94, 96 and 98 may not be the same. Accordingly, the controller 130 may individually perform a calibration operation to the plurality of memory dies 90, 92, 94, 96 and 98. For example, the controller 130 may select one among a plurality of channels CH1, CH2, CH3 and CH4 sequentially to perform the calibration operation. After selecting the first channel CH1, the controller 130 may perform the calibration operation to each of the plural memory dies 90 and 92 which are coupled via the first channel CH1 to the controller 130. When the calibration operation for the plural memory dies 90 and 92 coupled via the first channel CH1 to the controller 130 is completed, the controller 130 can select the second channel CH2 among the plurality of channels CH1, CH2, CH3 and CH4 for the calibration operation.

According to an embodiment, the controller 130 may randomly (or arbitrarily) select one among the plurality of channels CH1, CH2, CH3 and CH4 to perform the calibration operation. In addition, according to another embodiment, the controller 130 may select one among the plurality of memory dies 90, 92, 94, 96 and 98, regardless of which channel the die is coupled to, to perform the calibration operation.

The controller 130 may sequentially or arbitrarily perform the calibration operation to each of the plurality of memory dies 90, 92, 94, 96 and 98 during an initial (or setup) operation of the memory system 110. According to another embodiment, when an error occurs or the number of error bits increases while the memory system 110 performs a data input/output operation, the controller 130 may selectively perform the calibration operation on a specific memory die corresponding to the error or error bit. Further, after the memory system 110 is in an idle state or a power saving state for a predetermined time or longer before performing a data input/output operation, the controller 130 may perform the calibration operation on at least one memory die.

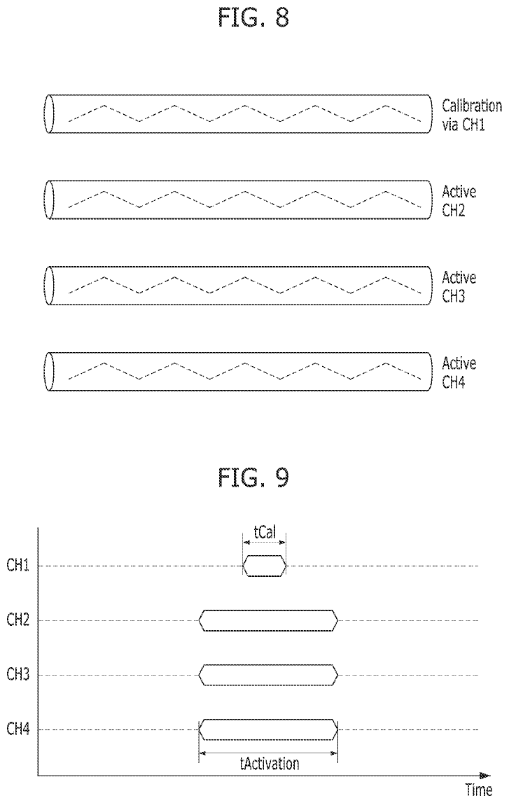

FIG. 8 illustrates a channel status for the calibration operation. In FIG. 8, a case in which four channels CH1, CH2, CH3 and CH4 are included will be described as an example like the memory system 110 described in FIG. 7.

Referring to FIGS. 7 and 8, when the controller 130 performs the calibration operation to one of the memory dies 90 and 92 coupled via the first channel CH1 to the controller 130, all other channels CH2, CH3 and CH4 are in an active state. As described in FIG. 4, the active state (or activation state) of a channel may indicate a state in which data or signals are being transmitted through the corresponding channel.

When the other channels CH2, CH3 and CH4 are maintained in an active state, the operating environment and conditions such as an operating condition that could be the most error prone may be set to become the worst in data communication performed through the first channel CH1. While all other channels CH2, CH3 and CH4 are in an active state, the calibration operation is performed to the memory die 90 or 92 coupled via the first channel CH1, so that it is possible to reduce the possibility of errors that may occur in the data communication between the memory die 90 or 92 and the controller 130.

Although not shown, while the calibration operation is performed on one of the other channels CH2, CH3 and CH4, all channels in which the calibration operation is not performed may be maintained in an active state. In order to maintain the channel in an active state, the controller 130 may transmit program data to a memory die connected through a corresponding channel or may receive read data from the memory die through the corresponding channel. According to an embodiment, the program data or read data may include arbitrary test data, fake data, or dummy data which is not actually programmed nor stored in non-volatile memory cells of the memory die. In addition, when the controller 130 transmits the fake data or dummy data to the memory die through a channel in an active state, the corresponding memory die may not receive or recognize the fake data or dummy data because data transmitted for maintaining the active state of the channel is the fake data or dummy data.

FIG. 9 illustrates data transmission windows of the calibration operation and the channel activation. Specifically, referring to FIGS. 7 to 9, the controller 130 performs the calibration operation to one of the memory dies 90 and 92 coupled via the first channel CH1 among a plurality of channels CH1, CH2, CH3 and CH4 to the controller 130.

Referring to FIG. 9, the calibration window tCal for the calibration operation performed to one of the memory dies 90 and 92 coupled via the first channel CH1 to the controller 130 is smaller or shorter than the activation window tActivation for the activation operation performed to the other channels CH2, CH3 and CH4. Further, the window tCal for the calibration operation may belong to, or completely overlap with, the activation window tActivation for the activation operation. That is, before the calibration operation performed through the first channel CH1 starts, the activation operation begins on the other channels CH2, CH3 and CH4. After the calibration operation performed through the first channel CH1 is completed, the activation operation may be completed on the channels CH2, CH3 and CH4. Through this, while the calibration operation is performed through a specific channel, all other channels can be maintained in an active state.

In FIG. 9, the activation windows for the activation operation performed on the other channels CH2, CH3 and CH4 are the same as each other. According to an embodiment, the activation windows for the activation operation performed on each of the channels CH2, CH3 and CH4 are different, so that the activation windows for the activation operation could cover, or overlap, the calibration windows tCal for the calibration operation. Through this operation, because the calibration operation for one of the memory dies 90 and 92 coupled via the first channel CH1 can be performed under a poor operating environment within the memory system 110, reliability of data communication performed after the calibration operation can be improved.

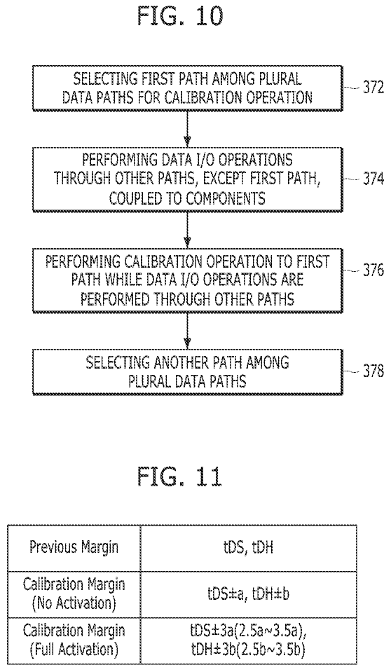

FIG. 10 illustrates a method for operating a memory system according to an embodiment of the present disclosure.

Referring to FIG. 10, the method of operating the memory system includes selecting a first path from among plural data paths to perform a calibration operation (372), performing data input/output operations with devices or components coupled to other paths other than the first path among the plural data paths (374), performing the calibration operation on the first path while performing the data input/output operations on the other paths (376), and selecting another path coupled to a device or a component requiring the calibration operation (378).

The controller 130 in the memory system 110 (refer to FIGS. 1 to 3 and 7) may determine the first path among the plural data paths for the calibration operation (372). For example, the plural data paths may include a plurality of channels between the controller 130 and plural memory dies within the memory system 110. Specifically, the controller 130 may select a specific component (e.g., memory die) coupled via the first path. According to an embodiment, when plural components are coupled to the controller 130 via the first path, the plural components may be selected sequentially for the calibration operation.

When a target (i.e., a specific component included in the memory system 110) coupled via the first path for performing the calibration operation is determined, the controller 130 may activate all other unselected paths, except the first path on which the calibration operation is to be performed. For example, when there are four data paths in the memory system 110, the controller 130 may activate three other paths except for the first path. For activation on three other paths, the controller 130 may select at least one component (e.g., a memory die) coupled via each of all unselected paths to the controller 130. Thereafter, the controller 130 may perform data communication (i.e., data transmission/reception) with selected components (e.g., selected memory dies) (374).

Transmitting and receiving data is one of the ways to activate the data path. For example, the operation 374 of activating all unselected paths can include selecting at least one memory die coupled via each of all unselected paths and performing a program operation or a read operation on selected memory dies. In this case, the controller 130 or the selected memory die may transmit/receive a specific data pattern which may produce the most interference and noise through all unselected paths for data communication. According to an embodiment, even if data is not received by a specific component such as a memory die, the controller 130 may activate a data path by transmitting data to the specific component through the data path.

The controller 130 may perform the calibration operation for data communication between the memory die coupled via the first path to the controller 130, while all unselected paths are activated (376). According to an embodiment, the calibration operation includes a first calibration operation for data communication in a first direction from the controller 130 to the memory die and a second calibration operation for data communication in a second direction from the memory die to the controller 130. That is, the calibration operation may be performed in both directions on the first path. According to an embodiment, a data transmission window for data communication with a memory die coupled via an activated path may be wider or longer than the calibration for the calibration operation. The calibration window for the calibration operation may completely overlap the data transmission window for the data communication.

Referring to FIG. 7, the controller 130 may be coupled to the plural memory dies via plural data paths. Although not illustrated, the method of operating the memory system may further include selecting another memory die coupled via the first path or selecting one of all unselected paths, when the calibration operation with the specific memory die coupled via the first path is completed. Through this, the controller 130 may individually perform the calibration operation for each of the plural memory dies. The results of the calibration operation performed individually for each memory die may be different. Although not shown, the method of operating the memory system may further include storing the calibration result determined through the calibration operation in correspondence with the memory die. After the calibration operation is completed, when the controller 130 outputs data to a specific memory die or receives data from the specific memory die, the controller 130 may sense and recognize the data based on the calibration result stored corresponding to the memory die.

FIG. 11 illustrates an effect of the calibration operation with the channel activation.

Referring to FIG. 11, data transmission window margins tDS, tDH before a calibration operation performed to the memory die 90 (refer to FIG. 1) coupled to the controller 130 via a specific channel can be compared with two results. A first result tDS±a, tDH±b is obtained from a case, Calibration Margin (No Activation), when other channels are not activated while the calibration operation is performed to the specific channel. A second result tDS±3a(2.5a˜3.5a), tDH±3b(2.5b˜3.5b) is obtained from another case, Calibration Margin (Full Activation), when the other channels are activated while the calibration operation is performed to the specific channel. Herein, the data transmission window margins tDS, tDH may be determined based on a setup time tDS, a hold time tDH, and variables ‘a’, ‘b’ which are time values.

The first result when a channel other than the corresponding channel is not activated includes the variables ‘a,’ ‘b.’ But, the second result when the other channels are activated includes information about variables ‘3a,’ ‘3b.’ As compared with the first and second results, calibration results may be increased by about 3 times (i.e., ‘a’ to ‘3a’). According to an operating environment of the calibration operation shown in FIG. 11, the calibration results may include a difference of 2.5 to 3.5 times. This difference in the calibration results may be used to improve operational reliability in data communication within the memory system 110 (see FIGS. 1 to 3) operating at high speed.

A memory system or a data processing system according to an embodiment of the present disclosure may support a fast data input/output speed or a fast data processing speed.

In addition, even if a plurality of data transmission/reception operations are performed simultaneously or in parallel via a plurality of data paths in the memory system, an embodiment of the present disclosure can reduce errors that occur during data transmission/reception operations, thereby improving the operating performance of the memory system.

While the present teachings have been illustrated and described with respect to the specific embodiments, it will be apparent to those skilled in the art in light of the present disclosure that various changes and modifications may be made without departing from the spirit and scope of the disclosure as defined in the following claims.

What is claimed is:

1. A memory system, comprising:
a memory device including a plurality of memory dies; and
a controller coupled to the plurality of memory dies via plural data paths,
wherein the controller is configured to select a first path among the plural data paths, activate unselected paths among the plural data paths, and perform a calibration operation for data communication between the controller and a first memory die coupled to the controller via the first path among the plural memory dies while the unselected paths are activated.

2. The memory system according to claim 1,
wherein the controller is configured to perform the calibration operation for each memory die individually, and
wherein an overall calibration window for the calibration operation is overlapped with an activation window.

3. The memory system according to claim 2, wherein the controller is further configured to store a result of the calibration operation performed for each memory die.

4. The memory system according to claim 1, wherein the controller is further configured to perform the calibration operation to other memory dies coupled to the controller via the first path after the calibration operation to the first memory die is completed, and select a second path among the unselected paths after the calibration operation to the other memory dies is completed.

5. The memory system according to claim 1, wherein the controller is further configured to select a second path among the unselected paths for the calibration operation after the calibration operation to the first memory die is completed and before the calibration operation to other memory dies coupled to the controller via the first path starts.

6. The memory system according to claim 1, wherein the controller is configured to activate the unselected paths by transmitting dummy data with a program command to at least one memory die coupled to the controller via each of the unselected paths.

7. The memory system according to claim 1, wherein the controller is configured to activate the unselected paths by transmitting dummy data without a program command to at least one memory die coupled to the controller via each of the unselected paths.

8. The memory system according to claim 1, the controller is configured to activate the unselected paths by transmitting a read command to at least one memory die coupled to the controller via each of the unselected paths.

9. The memory system according to claim 1, wherein the calibration operation includes a first calibration operation for first data communication from the controller to the first memory die and a second calibration operation for second data communication from the first memory die to the controller.

10. The memory system according to claim 1, wherein the controller is configured to activate the unselected paths with a data pattern which causes noise or interference among the plural data paths.

11. A method for operating a memory system including a plurality of memory dies, comprising:
selecting a first path among plural data paths for performing a calibration operation, the plural data paths being coupled between a controller and the memory dies;
activating unselected paths among the plural data paths; and
performing the calibration operation for data communication between the controller and a first memory die coupled to the controller via the first path among the plural memory dies while the unselected paths are activated.

12. The method according to claim 11, wherein the selecting of the first path includes selecting at least one memory die coupled to the controller via the first data path.

13. The method according to claim 11, wherein the activating of the unselected paths includes:
selecting at least one memory die coupled to the controller via each of the unselected paths; and
performing the data communication to the selected memory die.

14. The method according to claim 11,
wherein the calibration operation is individually and sequentially performed to other dies among the plurality of memory dies, and
wherein an overall calibration window for the calibration operation is overlapped with an activation window.

15. The method according to claim 11, further comprising either selecting a second path among the unselected paths or selecting another memory die coupled to the controller via the first path, after the performing of the calibration operation is completed.

16. The method according to claim 11, wherein the activating the unselected paths includes:
selecting at least one memory die coupled to the controller via each of the unselected paths; and
performing a program operation or a read operation with the at least one memory die.

17. The method according to claim 16, wherein the performing of the program operation or the read operation includes transmitting a data pattern which causes noise or interference among the plural data paths.

18. The method according to claim 11, further comprising storing a result of the calibration operation.

19. A data input/output apparatus comprising plural data transceivers, which are configured to perform data communication to plural devices via plural data paths and arranged to correspond to the plural data paths, wherein a data transceiver selected among the plural data transceivers performs a calibration operation while unselected transceivers among the plural data transceivers perform data input/output operations, and wherein an overall calibration window for the calibration operation is overlapped with a data input/output window for the data input/output operations.

20. The data input/output apparatus according to claim 19, wherein each of the plural data transceivers includes:
a first path allocated for data transmission;
a second path allocated for data reception;
a delay unit configured to delay the reception data by a delay amount in the second path; and
a calibration unit configured to adjust the delay amount through the calibration operation.
